(19) United States
(12) Patent Application Publication
(10) Pub. No.: US 2011/0076824 A1
(43) Pub. Date: Mar. 31, 2011

(54) FABRICATION METHOD OF PHASE CHANGE RANDOM ACCESS MEMORY DEVICE

(75) Inventors: Kang Sik CHOI, Gyeonggi-do (KR); Sung Cheoul KIM, Gyeonggi-do (KR)

(73) Assignee: HYNIX SEMICONDUCTOR INC., Gyeonggi-do (KR)

(21) Appl. No.: 12/839,458

(22) Filed: Jul. 20, 2010

(30) Foreign Application Priority Data
Sep. 30, 2009 (KR) 10-2009-0093618

(51) Int. Cl. H01L 21/02

(52) U.S. Cl. 438/381; 257/E21.003

(57) ABSTRACT

A method of fabricating a phase change random access memory device includes forming a sacrificial layer of a predetermined height within a bottom electrode contact hole. The method also includes forming an insulating layer on a whole resultant structure including the bottom electrode contact hole. The method also includes forming a spacer on a sidewall of the bottom electrode contact hole by etching the insulating layer and removing the sacrificial layer.

### CROSS-REFERENCES TO RELATED APPLICATION

This application claims priority under 35 U.S.C. 119(a) to Korean application number 10-2009-0093618, filed on Sep. 30, 2009, in the Korean Patent Office, which is incorporated by reference in its entirety as if set forth in full.

### BACKGROUND

1. Technical Field

The inventive concept relates to semiconductor devices and, more particularly, to a method of fabricating a phase change random access memory device.

2. Related Art

Phase change random access memories (PCRAMs) are non-volatile memory devices that are next-generation memory devices which provides DRAM grade performance with respect to reproduction speed and reprogramming number, etc.

The PCRAMs reversibly control phase change transitions between crystalline or amorphous states so that they can be used in SET or RESET states to store data. In particular, when the phase change material is set in the RESET state, then a large amount of current should be applied to the phase change material for a short amount of time. This RESET current is a substantial factor which directly affects the operation performance of the PCRAM. As a result, the RESET current is the lower the driving power is.

The RESET current is closely related to the diameter of a bottom electrode contact (BEC) which serves as a heater for the phase change material layer. The smaller the diameter of the BEC contacted with the phase change material layer is, the more reduced the reset current is.

Accordingly, to minimize the diameter of the BEC which is contacted with the phase change material layer, the method for forming a spacer within the BEC hole was suggested. However, as the size of the device is decreased, the diameter of BEC hole is necessarily decreased. According when an etch back process for forming the spacer is carried out, it causes a not-open phenomenon that corresponds to a bottom of the BEC hole not being exposed.

The phenomenon can be solved by carrying out over etching during the space formation process. However, the bottom electrode contact at the bottom of the BEC hole can be inadvertently removed due to the over etching so that the effective diameter of the BEC contact ends up being increased.

FIGS. 1a and 1b are sectional views illustrating a method of forming BEC in a conventional PCRAM.

Referring to FIG. 1a, an interlayer insulating layer 12 is formed on a semiconductor substrate 10 including a bottom structure and patterned to form a BEC hole 104. A bottom electrode 14 and a BEC 16 having predetermined heights are formed within the BEC hole 104. Next, a spacer insulating layer 18 is formed on a resultant structure.

Referring to FIG. 1b, the spacer insulating layer 18 is etched by a spacer etching process to form a spacer 18A on a sidewall of the BEC hole 104. At this time, the spacer insulating layer 18 is over etched to prevent the BEC contact 16 from being unexposed so that a portion of the BEC contact 16 is removed.

Under this state, when a phase change material is buried within the BEC hole, an effective diameter of the bottom electrode which is contacted with the phase change material is increased above a desired size.

As a result, it can not reduce the RESET current so that it can not improve the operation characteristic of the PCRAM.

### SUMMARY

According to one exemplary embodiment, a method of fabricating a phase change random access memory device includes forming a sacrificial layer of a predetermined height within a bottom electrode contact hole, forming an insulating layer on a resultant structure including the bottom electrode contact hole, forming a spacer on a sidewall of the bottom electrode contact hole by etching the insulating layer, and removing the sacrificial layer.

According to another exemplary embodiment, a method of fabricating a phase change random access memory device includes sequentially forming a bottom electrode and a sacrificial layer of predetermined heights within a bottom electrode contact hole, forming an insulating layer on a resultant structure including the bottom electrode contact hole, forming a spacer on a sidewall of the bottom electrode contact hole by etching the insulating layer, and removing the sacrificial layer to expose a surface of the bottom electrode.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1a and 1b are sectional views illustrating a method of forming BEC in a conventional phase change random access memory device;

FIGS. 2 through 9 are sectional views illustrating a method of fabricating a phase change random access memory device according to an exemplary embodiment of the inventive concept;

FIG. 10 is a sectional view illustrating a method of fabricating a phase change random access memory device according to another exemplary embodiment of the inventive concept;

FIG. 11 is a sectional view illustrating a method of fabricating a phase change random access memory device according to still another exemplary embodiment of the inventive concept; and

FIG. 12 is a sectional view illustrating a method of fabricating a phase change random access memory device according to still another exemplary embodiment of the inventive concept.

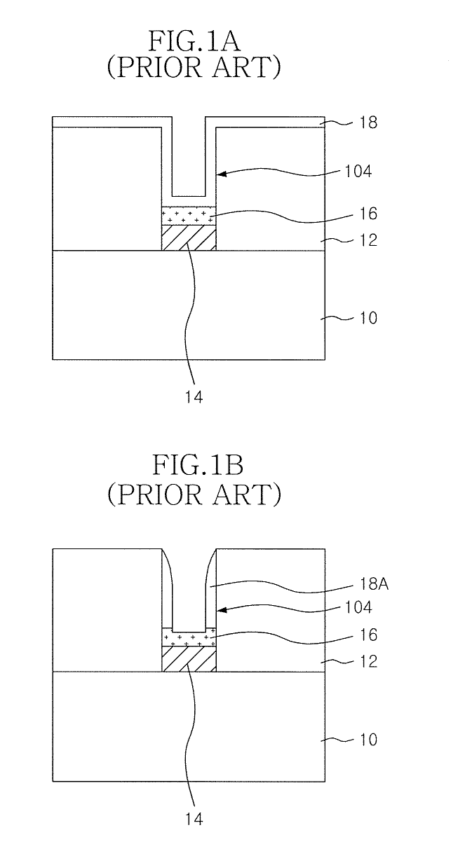

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

A phase change random access memory device may use a transistor or a diode as a switching device. If a specific bottom electrode is selected by the switching device, a bottom electrode contact is heated and a phase change material contacted with the bottom electrode contact is phase-changed. The bottom electrode and the bottom electrode contact are fabricated by various forms. There are disclosed a method of burying the bottom electrode and the bottom electrode contact within the bottom electrode contact hole and a method of forming the bottom electrode contact hole on the bottom electrode and then forming the bottom electrode contact within the bottom electrode contact hole.

Hereinafter, a method of forming the bottom electrode and the bottom electrode contact within the bottom electrode contact hole will be disclosed further. It is understood herein that the inventive concept is not limited thereto, and it can be adopted to any structure for forming a spacer within the bottom electrode contact hole.

FIGS. 2 through 9 are sectional views illustrating a method of fabricating a phase change random access memory device according to an exemplary embodiment of the inventive concept.

Referring to FIG. 2, an interlayer insulating layer 103 is formed on a semiconductor substrate 101 which a bottom structure including a switching device (not shown) is formed thereon. The interlayer insulating layer 103 is etched to form a bottom electrode contact hole 104. A bottom electrode 105 of a predetermined height is formed within the bottom electrode contact hole 104 and then a sacrificial layer 107 is formed on a resultant structure. The sacrificial layer 107 may be comprised of an oxide material.

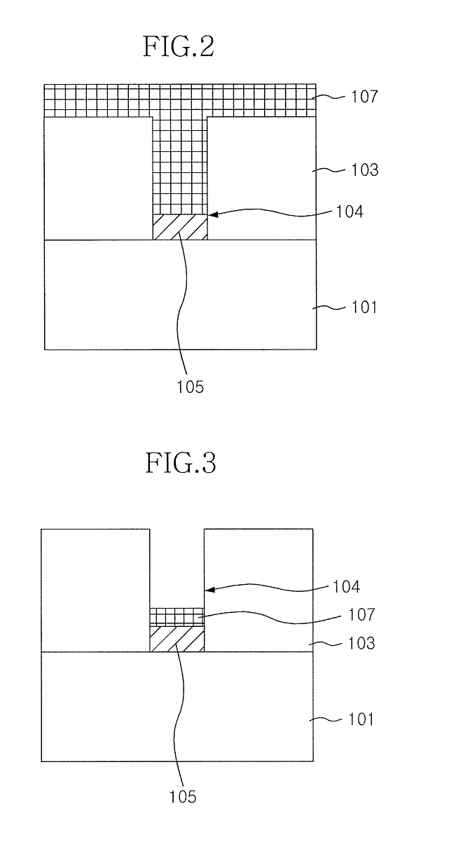

FIG. 3 shows that the sacrificial layer 107 of a predetermined height remains only on the bottom electrode 105 by an etching process, especially an etch back process.

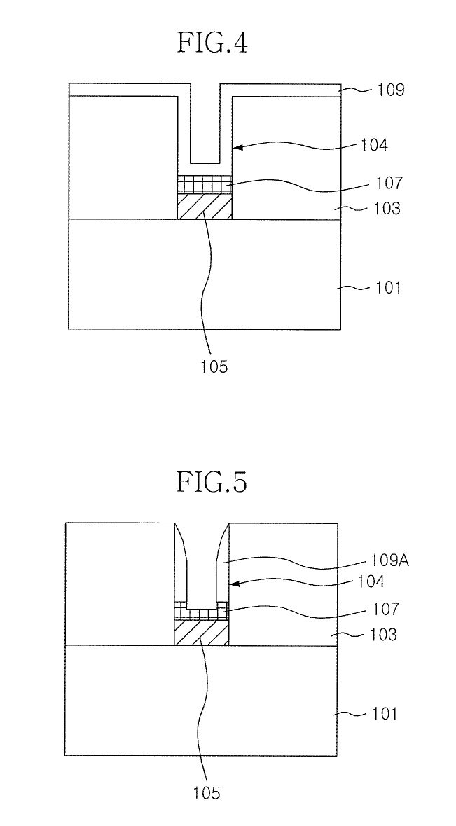

Referring to FIG. 4, a spacer insulating layer 109 is formed on the resultant structure including the bottom electrode contact hole 104 and referring to FIG. 5, the spacer insulating layer 109 is etched by a spacer etching process to form a spacer 109A. At this time, the etching degree of the spacer insulating layer 109 in the spacer formation process depends on a diameter of the bottom electrode contact hole 104. In particular, as the shrinkage is increased, it is preferable to increase the etching ratio of the spacer insulating layer 109. According to the over etching, a portion of the sacrificial layer 107 may be removed as shown in FIG. 5.

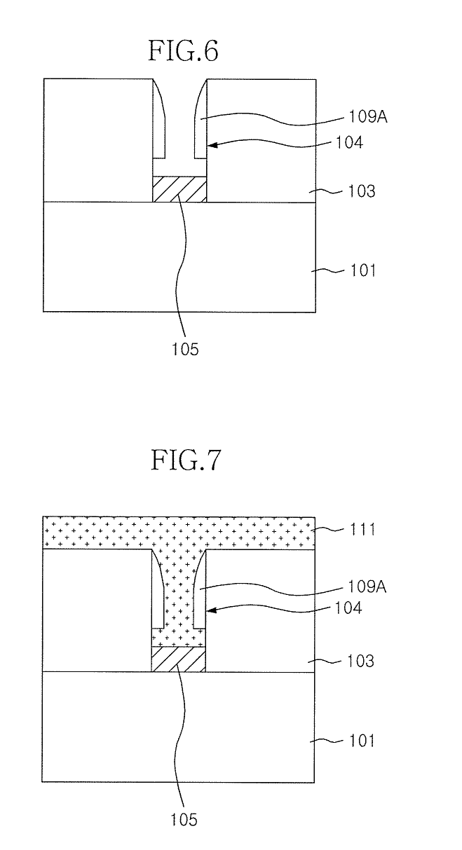

After the spacer 109A is formed, the unnecessary sacrificial layer 107 is removed. FIG. 6 shows that the sacrificial layer 107 is removed. If the sacrificial layer 107 is comprised of an oxide material, it may be removed by a wet etching process.

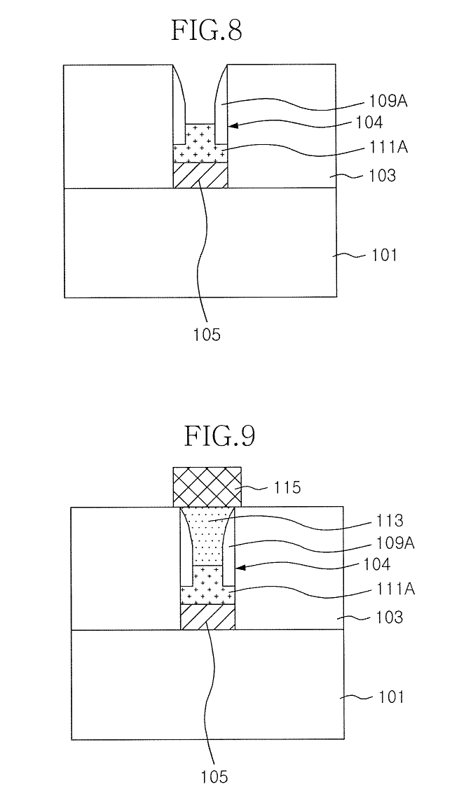

Referring to FIG. 7, a conductive layer 111 is formed on a resultant structure and referring to FIG. 8, the conductive layer 111 is etched back to form a bottom electrode contact 111A of a predetermined height within the bottom electrode contact hole 104.

Conventionally, after the bottom electrode contact is formed, the spacer etching process is carried out so that the portion of the bottom electrode contact is removed and the substantial diameter of the bottom electrode contact is increased. On the contrary, in the exemplary embodiment, the spacer is formed under the state that the sacrificial layer is formed and the bottom electrode contact is formed at a portion where the sacrificial layer is removed so that it can prevent the bottom electrode contact from being removed.

Furthermore, it is easy to control the height of the bottom electrode contact in etching back the conductive layer 111. Accordingly, as shown in FIG. 8, the substantial diameter of the bottom electrode contact 111A can be effectively reduced, in case where the height of the bottom electrode contact 111A is controlled higher than the height of the sacrificial layer 107 that is, the height from the bottom electrode 105 to the bottom surface of the spacer 109A.

FIG. 9 shows that a phase change material pattern 113 is formed within the bottom electrode contact hole 104 and an upper electrode 115 is formed to be contacted with the phase change material pattern 113.

Because the bottom electrode contact 111A is formed following the spacer etching process, it is not absolutely affected by the spacer etching process so that the contact area between the bottom electrode contact 111A and the phase change material pattern 113 can be minimized. In particular, under the consideration of the diameter of the bottom electrode contact hole 104 by the formation of the spacer 109A, in case where the height of the bottom electrode contact 111A approaches the point that the diameter of the bottom electrode contact hole 104 is minimized, the reduction effect of the RESET current can be maximized.

Although burying the bottom electrode and the phase change material pattern within the bottom electrode contact hole 104 in is illustrated FIG. 9, it is understood herein that this inventive concept is not limited thereto.

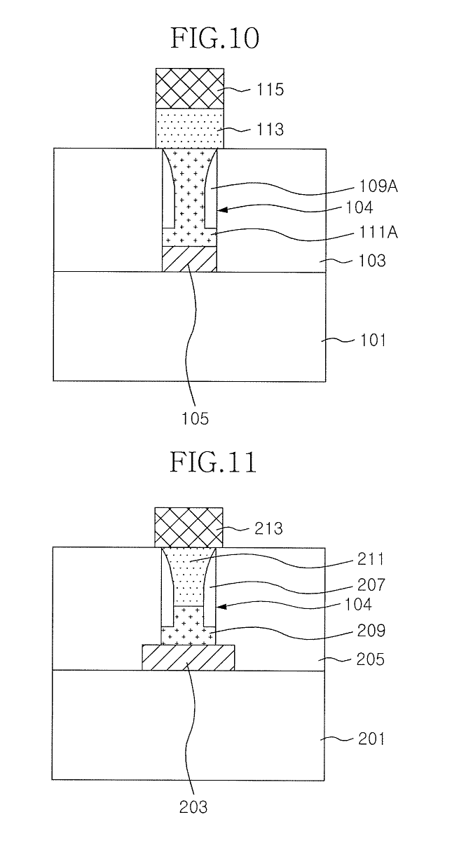

FIG. 10 is a sectional view illustrating a method of fabricating a phase change memory device according to another exemplary embodiment of the inventive concept.

After the conductive layer 111 is formed as shown in FIG. 7, the conductive layer 111 is buried within the bottom electrode contact hole 104 by a planarizing process to form the bottom electrode contact 111A. The phase change material pattern 113 and an upper electrode 115 are formed to be contacted with the bottom electrode contact 111A.

When the PCRAM is fabricated, it may bury the bottom electrode within the bottom electrode contact hole 104, but it may form the bottom electrode contact hole 104 on the bottom electrode contact. At this case, a spacer may also be formed on an inner wall of the bottom electrode contact hole 104 so as to reduce the diameter of the bottom electrode contact.

FIG. 11 is a sectional view illustrating a method of fabricating a phase change random access memory device according to still another exemplary embodiment of the inventive concept.

In another exemplary embodiment, a bottom electrode 203 is formed on a semiconductor substrate 201 which a bottom structure such as a switching device (not shown) is formed on. An interlayer insulating layer 205 is formed on the semiconductor substrate 201 and the bottom electrode 203 and etched to form a bottom electrode contact hole 104 exposing an upper surface of the bottom electrode 203.

Similar to the above exemplary embodiments, a sacrificial layer (not shown) is formed at the bottom of the bottom electrode contact hole 104. A spacer 207 is formed by a spacer insulating layer formation and etching process and then the sacrificial layer is removed. Subsequently, a bottom electrode contact 209 of a predetermined height is formed at a bottom of the bottom electrode contact hole 104 where the spacer 207 is formed on a sidewall. According to this, the spacer is formed so to restrict the bottom electrode contact 209 so that the diameter of the bottom electrode contact 209 can be reduced.

Next, a phase change material pattern 211 is buried within the bottom electrode contact hole 104 and an upper electrode 213 is formed to be contacted with the phase change material pattern 211.

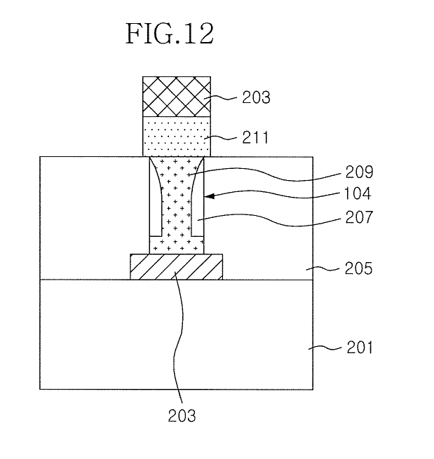

FIG. 12 is a sectional view illustrating a method of fabricating a phase change random access memory device according to still yet another exemplary embodiment of the inventive concept.

In this exemplary embodiment, differently from another exemplary embodiment of FIG. 11, after the sacrificial layer is removed, the conductive layer is buried within a bottom electrode contact hole 104 and planarized so that the bottom electrode contact 209 is buried within the bottom electrode contact hole 104.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A method of fabricating a phase change random access memory device, comprising:
forming a sacrificial layer of a predetermined height within a bottom electrode contact hole;
forming an insulating layer on a resultant structure including the bottom electrode contact hole;
forming a spacer on a sidewall of the bottom electrode contact hole by etching the insulating layer; and
removing the sacrificial layer.

2. The method of claim 1, wherein the sacrificial layer comprises an oxide material.

3. The method of claim 2, wherein the sacrificial layer is removed by a wet etching process.

4. The method of claim 1, after the removing the sacrificial layer, further comprising:
forming a conductive layer on the resultant structure including the bottom electrode contact hole; and
forming a bottom electrode contact of a predetermined height by selectively removing the conductive layer.

5. The method of claim 4, further comprising burying a phase change material within the bottom electrode contact hole so that the phase change material contacts with the bottom electrode contact.

6. The method of claim 1, after the removing the sacrificial layer, further comprising:
forming a conductive layer on the resultant structure including the bottom electrode contact hole; and
forming a bottom electrode contact to be buried within the bottom electrode contact hole by planarizing the conductive layer.

7. The method of claim 6, further comprising forming a phase change material pattern contacted with the bottom electrode contact.

8. A method of fabricating a phase change random access memory device, comprising:
sequentially forming a bottom electrode and a sacrificial layer of predetermined heights within a bottom electrode contact hole;
forming an insulating layer on the resultant structure including the bottom electrode contact hole;
forming a spacer on a sidewall of the bottom electrode contact hole by etching the insulating layer; and
removing the sacrificial layer to expose a surface of the bottom electrode.

9. The method of claim 8, wherein the sacrificial layer comprises an oxide material.

10. The method of claim 9, wherein the sacrificial layer is removed by a wet etching process.

11. The method of claim 8, after removing the sacrificial layer, further comprising:
forming a conductive layer on the resultant structure including the bottom electrode contact hole; and
forming a bottom electrode contact of a predetermined height within the bottom electrode contact hole by selectively removing the conductive layer.

12. The method of claim 11, further comprising burying a phase change material within the bottom electrode contact hole so that the phase change material contacts with the bottom electrode contact.
